(19) United States
(12) Patent Application Publication
(10) Pub. No.: US 2025/0172884 A1
(43) Pub. Date: May 29, 2025

(54) RETICLE PRESSING DEVICE AND RETICLE BOX USING THE SAME

(71) Applicant: GUDENG PRECISION INDUSTRIAL CO., LTD., NEW TAIPEI CITY (TW)

(72) Inventors: Ming-Chien CHIU, NEW TAIPEI CITY (TW); Yung-Chin PAN, NEW TAIPEI CITY (TW); Yu-Chen CHU, NEW TAIPEI CITY (TW); Chi-Chuan HUANG, NEW TAIPEI CITY (TW)

(73) Assignee: GUDENG PRECISION INDUSTRIAL CO., LTD., NEW TAIPEI CITY (TW)

(21) Appl. No.: 18/679,096

(22) Filed: May 30, 2024

Related U.S. Application Data
(60) Provisional application No. 63/603,815, filed on Nov. 29, 2023.

(30) Foreign Application Priority Data
Apr. 18, 2024 (TW) 113114561

(51) Int. Cl. G03F 7/00; H01L 21/673

(52) U.S. Cl. CPC G03F 7/70741; H01L 21/67359

(57) ABSTRACT

A reticle pressing device is applied to a reticle box used to accommodate a reticle. The reticle pressing device includes a reticle pressing board, a pressing member, and an adjusting member. The pressing member is disposed on the reticle pressing board. The pressing member includes a pushing portion. The pushing portion pushes the reticle pressing board correspondingly according to movement range of the pressing member toward the reticle pressing board, so that the reticle pressing board moves laterally relative to the pressing member. The adjusting member is disposed in the reticle pressing board through the pressing member. The adjusting member is used to adjust the movement range of the pressing member, so that the pushing portion pushes toward the reticle pressing board until the reticle is fixed, or adjusts the pushing portion of the pressing member to move away from the reticle and release pushing force.

### CROSS-REFERENCE TO RELATED APPLICATION

This application claims priority to U.S. Provisional Application Ser. No. 63/603,815, filed Nov. 29, 2023, and Taiwan Application Serial Number 113114561, filed Apr. 18, 2024, the disclosures of which are incorporated herein by reference in their entireties.

### BACKGROUND

### Technical Field

The present disclosure relates to a reticle pressing device and a reticle box using the same.

### Description of Related Art

In the semiconductor industry, reticles play a very important role in the manufacturing processes. Whether it is traditional yellow lithography or etching technologies, or even the recent extreme ultraviolet lithography (EUVL) process, they cannot be separated from the use of reticles.

Among many industries directly or indirectly related to semiconductors, industries related to optoelectronics are also a very important one. When manufacturing a large-sized panel, the size of the reticle used in the manufacturing process also changes with the size of the panel.

However, when a large-size reticle is carried in a reticle box, the accompanying inertial motion will become more severe. During the handling or transmission process of the large-sized reticle, it is more likely to be shaken, hit, or even caused the entire reticle container to topple due to insufficient transportation accuracy, which will further cause damage to the large-sized reticle. Not only that, the methods of the large-size reticle boxes currently on the market for pressing reticles may cause loosening problems, which may cause the large-size reticle to jump around in the reticle box during transportation, thereby producing particles that can contaminate the reticle. Furthermore, the components of an existing reticle pressing device used in the reticle box are independent of each other. Therefore, a user needs to use both hands during assembly and disassembly (for example, holding the device firmly with one hand and fastening a screw to the reticle box through the device with the other hand), which makes the operation difficult and unstable.

Accordingly, how to provide a reticle pressing device to solve the foregoing problem becomes an important issue to be solved by those in the industry.

### SUMMARY

An aspect of the disclosure is to provide a reticle pressing device and a reticle box using the same to solve the foregoing problem.

According to an embodiment of the disclosure, a reticle pressing device is applied to a reticle box. The reticle box is used to accommodate a reticle. The reticle pressing device includes a reticle pressing board, a pressing member, and an adjusting member. The pressing member is disposed on the reticle pressing board. The pressing member includes a pushing portion. The pushing portion pushes the reticle pressing board correspondingly according to a movement range of the pressing member toward the reticle pressing board, so as to make the reticle pressing board move laterally relative to the pressing member. The adjusting member is disposed in the reticle pressing board through the pressing member. The adjusting member is used to adjust the movement range of the pressing member, so that the pushing portion pushes toward the reticle pressing board until the reticle is fixed, or adjusts the pushing portion of the pressing member to move away from the reticle and release pushing force.

In one or more embodiments of the present disclosure, the pushing portion includes an elastic portion and an inclined surface coupled to the elastic portion. The pressing member is adjusted according to the adjusting member, so that the reticle pressing board is pushed toward the reticle or away from the reticle along an inclination angle of the inclined surface, and the elastic portion elastically deforms simultaneously with pushing force of the inclined surface.

In one or more embodiments of the present disclosure, the pressing member moves toward the reticle pressing board along a first axial direction, so as to make the pushing portion push the reticle pressing board to move laterally relative to the pressing member along a second axial direction. The pushing portion is inclined relative to the first axial direction and the second axial direction.

In one or more embodiments of the present disclosure, the pressing member further includes a body portion. The body portion is coupled to the pushing portion and for disposing the adjusting member. The pushing portion includes an elastic portion. The elastic portion elastically deforms along with a lateral movement of the body portion.

In one or more embodiments of the present disclosure, the adjusting member is rotatably coupled to the pressing member.

In one or more embodiments of the present disclosure, the pressing member has a through hole. The through hole has an expansion hole portion and a shrinkage hole portion that are connected to each other. A hole diameter of the expansion hole portion is greater than a hole diameter of the shrinkage hole portion. The adjusting member is placed in the expansion hole portion and coupled and positioned toward the shrinkage hole portion.

In one or more embodiments of the present disclosure, the shrinkage hole portion has a flange therein for coupling and positioning an annular engaging groove of the adjusting member.

In one or more embodiments of the present disclosure, the adjusting member includes a head portion, a fastening portion, and a pillar. The head portion is configured to abut against the pressing member and away from a side of the reticle pressing board. The fastening portion is configured to fasten the reticle box and adjust the movement range of the pressing member relative to the reticle pressing board according to a fastening degree of the fastening portion. An end of the pillar is coupled to the head portion. Another end of the pillar is coupled to the fastening portion. The pillar is disposed in the reticle pressing board through the pressing member.

In one or more embodiments of the present disclosure, the reticle pressing board, the pressing member, and the adjusting member are coupled together. The adjusting member includes a fastening portion. The fastening portion is configured to fasten the reticle box. When the fastening portion is unlocked from the reticle box, the reticle pressing board, the pressing member, and the adjusting member are removed from the reticle box together.

In one or more embodiments of the present disclosure, the reticle pressing board has a mounting hole. Two first retaining portions are provided on two sides of the mounting hole respectively. The pressing member includes a mounting portion. Two second retaining portions are provided on two sides of the mounting portion. The second retaining portions are respectively configured with the first retaining portions to retain each other.

According to an embodiment of the disclosure, a reticle box includes a box body and a reticle pressing device. The box body includes a wall portion. A plurality of platform portions are disposed on an inner side of the wall portion in an annular shape. Each of the platform portions has a fastening hole. The reticle pressing device is disposed in the box body. The box body has an accommodating space for accommodating a reticle. The reticle pressing device includes a reticle pressing board, a pressing member, and an adjusting member.

The reticle pressing board is disposed on one of the platform portions. The pressing member is disposed on the reticle pressing board. The pressing member includes a pushing portion. The pushing portion pushes the reticle pressing board correspondingly according to a movement range of the pressing member toward the reticle pressing board, so as to make the reticle pressing board move laterally relative to the pressing member. The adjusting member is disposed in the reticle pressing board through the pressing member. The adjusting member has a fastening portion. The fastening portion is configured to fasten to the fastening hole and adjust the movement range of the pressing member relative to the reticle pressing board according to a fastening degree of the fastening portion.

In one or more embodiments of the present disclosure, the pushing portion includes an elastic portion and an inclined surface coupled to the elastic portion. The pressing member is adjusted according to the adjusting member, so that the reticle pressing board is pushed toward the reticle or away from the reticle along an inclination angle of the inclined surface, and the elastic portion elastically deforms simultaneously with pushing force of the inclined surface.

In one or more embodiments of the present disclosure, the pressing member moves toward the reticle pressing board along a first axial direction, so as to make the pushing portion push the reticle pressing board to move laterally relative to the pressing member along a second axial direction. The pushing portion is inclined relative to the first axial direction and the second axial direction.

In one or more embodiments of the present disclosure, the pressing member further includes a body portion. The body portion is coupled to the pushing portion and for disposing the adjusting member. The pushing portion includes an elastic portion. The elastic portion elastically deforms along with a lateral movement of the body portion.

In one or more embodiments of the present disclosure, the adjusting member is rotatably coupled to the pressing member.

In one or more embodiments of the present disclosure, the pressing member has a through hole. The through hole has an expansion hole portion and a shrinkage hole portion that are connected to each other. A hole diameter of the expansion hole portion is greater than a hole diameter of the shrinkage hole portion. The adjusting member is placed in the expansion hole portion and coupled and positioned toward the shrinkage hole portion.

In one or more embodiments of the present disclosure, the shrinkage hole portion has a flange therein for coupling and positioning an annular engaging groove of the adjusting member.

In one or more embodiments of the present disclosure, the adjusting member further includes a head portion and a pillar. The head portion is configured to abut against the pressing member and away from a side of the reticle pressing board. An end of the pillar is coupled to the head portion. Another end of the pillar being coupled to the fastening portion. The pillar is disposed in the reticle pressing board through the pressing member.

In one or more embodiments of the present disclosure, the reticle pressing board, the pressing member, and the adjusting member are coupled together. When the fastening portion is unlocked from the reticle box, the reticle pressing board, the pressing member, and the adjusting member are removed from the reticle box together.

In one or more embodiments of the present disclosure, the reticle pressing board has a mounting hole. Two first retaining portions are provided on two sides of the mounting hole respectively. The pressing member includes a mounting portion. Two second retaining portions are provided on two sides of the mounting portion. The second retaining portions are respectively configured with the first retaining portions to retain each other.

Accordingly, in the reticle pressing device of the present disclosure, when the adjusting member is adjusted (fastened) toward the reticle pressing board, the pressing member that moves toward the reticle pressing board together pushes the reticle pressing board to move laterally with the inclined surface thereof, thereby achieving the purpose of making the reticle pressing board clamp the reticle laterally. In the embodiment in which the adjusting member is coupled to the shrinkage hole portion of the pressing member, when the adjusting member rotates, the reticle pressing board will retain the location of the pressing member so that the pressing member does not rotate together with the adjusting member. In the embodiment in which the pressing member has an engaging portion for engaging with the reticle pressing board, cooperating with the coupling relationship between the adjusting member and the shrinkage hole portion of the pressing member, the reticle pressing board can move upward along with the adjusting member together with the pressing member after the adjusting member is completely loosened from the fastening hole of the reticle box, so that the whole reticle pressing device can be detached from the reticle box (that is, the operation convenience can be increased).

It is to be understood that both the foregoing general description and the following detailed description are by examples, and are intended to provide further explanation of the disclosure as claimed.

### BRIEF DESCRIPTION OF THE DRAWINGS

The disclosure can be more fully understood by reading the following detailed description of the embodiment, with reference made to the accompanying drawings as follows:

FIG. 1 is a perspective view of a reticle pressing device according to an embodiment of the present disclosure;

FIG. 2 is an exploded view of the reticle pressing device in FIG. 1;

FIG. 3 is a perspective view of an adjusting member in FIG. 1;

FIG. 4 is a cross-sectional view of a pressing member and the adjusting member in FIG. 1;

FIG. 5 is a perspective view of the pressing member in FIG. 1;

FIG. 6 is a perspective view of a reticle box according to an embodiment of the present disclosure;

FIG. 7 is a partial enlarged exploded view of a box body and the reticle pressing device in FIG. 6;

FIG. 8 is a partial enlarged perspective view of the box body and the reticle pressing device in FIG. 7;

FIG. 9 is another partial enlarged perspective view of the box body and the reticle pressing device in FIG. 7; and

FIG. 10 is a partial cross-sectional view of the box body and the reticle pressing device in FIG. 7.

### DETAILED DESCRIPTION

Reference will now be made in detail to the present embodiments of the disclosure, examples of which are illustrated in the accompanying drawings. Wherever possible, the same reference numbers are used in the drawings and the description to refer to the same or like parts. However, specific structural and functional details disclosed herein are merely representative for purposes of describing example embodiments, and thus may be embodied in many alternate forms and should not be construed as limited to only example embodiments set forth herein. Therefore, it should be understood that there is no intent to limit example embodiments to the particular forms disclosed, but on the contrary, example embodiments are to cover all modifications, equivalents, and alternatives falling within the scope of the disclosure.

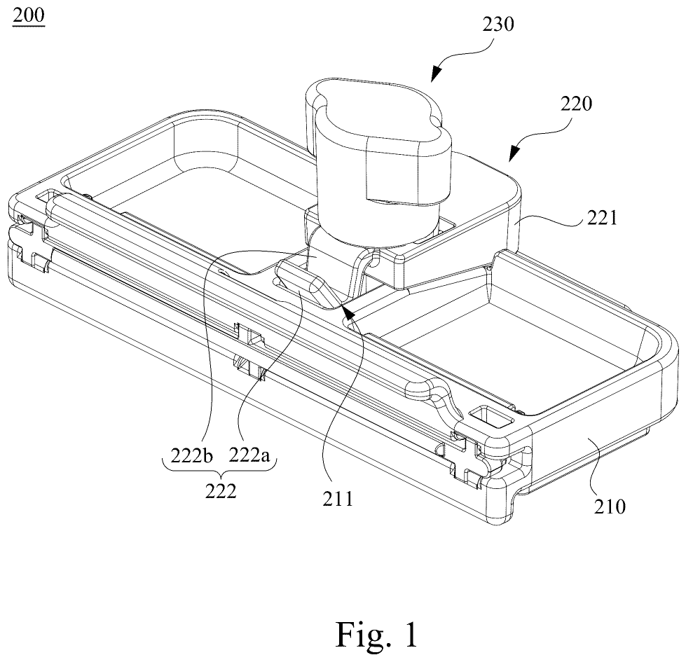

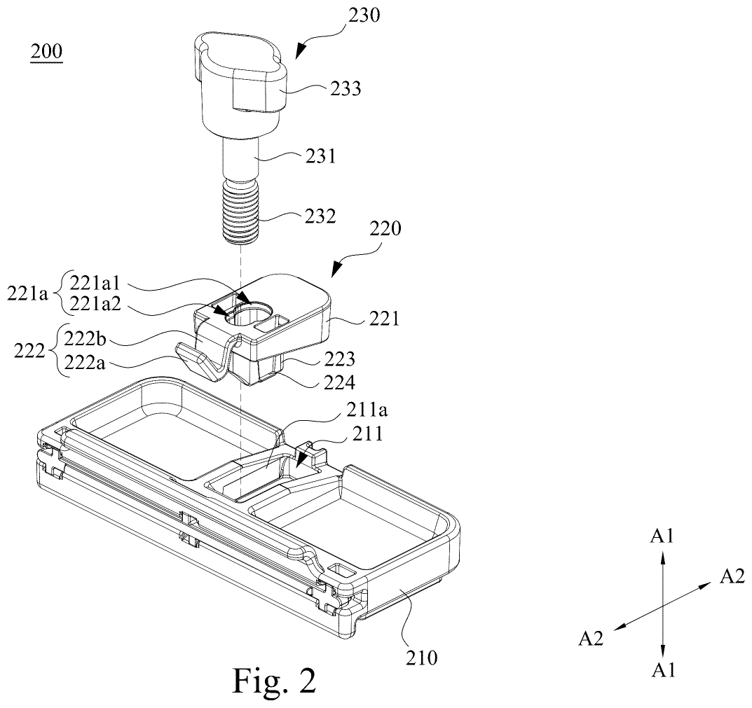

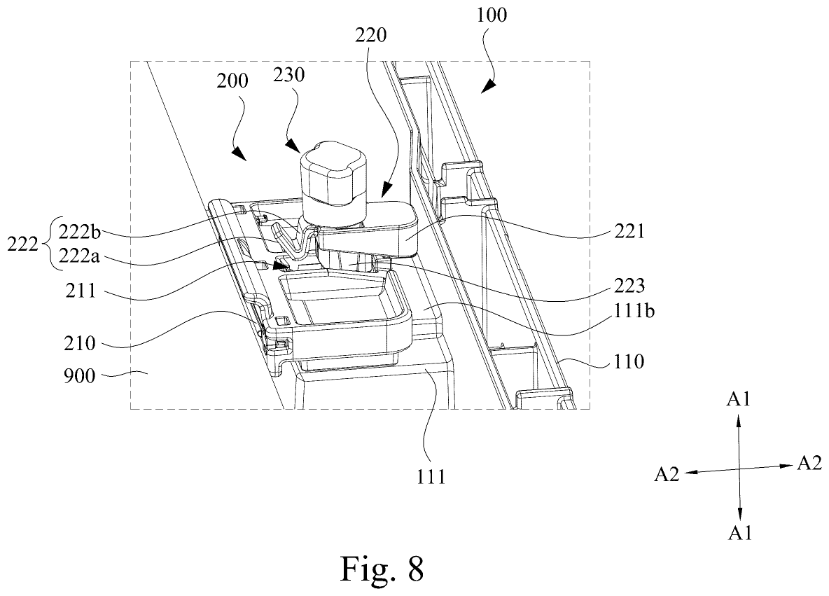

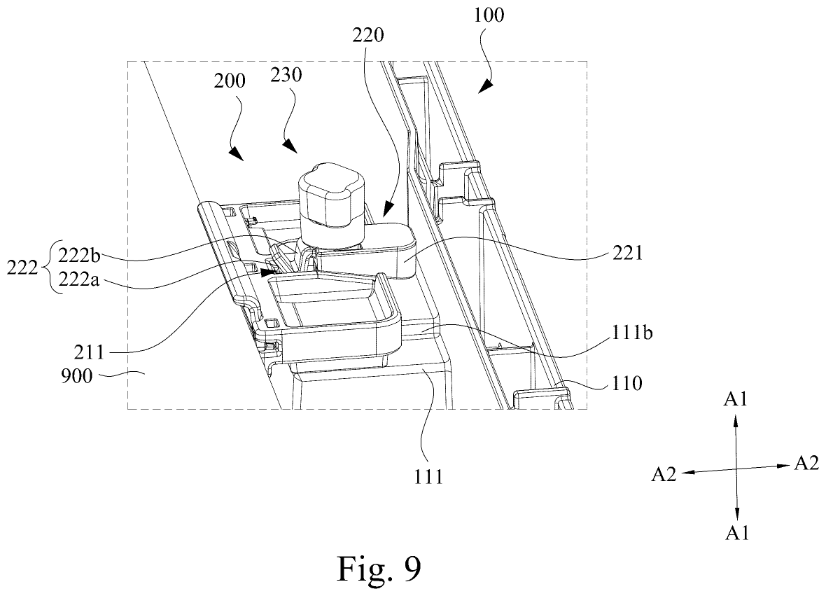

Reference is made to FIG. 1 and FIG. 2. FIG. 1 is a perspective view of a reticle pressing device 200 according to an embodiment of the present disclosure. FIG. 2 is an exploded view of the reticle pressing device 200 in FIG. 1. As shown in FIG. 1 and FIG. 2, in the present embodiment, the reticle pressing device 200 includes a reticle pressing board 210, a pressing member 220, and an adjusting member 230. The pressing member 220 includes a pushing portion 222. The pushing portion 222 is configured to push the reticle pressing board 210 correspondingly according to a movement range of the pressing member 220 toward the reticle pressing board 210, so as to make the reticle pressing board 210 move laterally relative to the pressing member 220. The adjusting member 230 is disposed in the reticle pressing board 210 through the pressing member 220, and is configured to adjust the movement range of the pressing member 220, so that the pushing portion 222 pushes toward the reticle pressing board 210 until a reticle 900 (see FIG. 9) is fixed, or adjusts the pushing portion 222 of the pressing member 220 to move away from the reticle 900 and release pushing force (see FIG. 8).

For example, as shown in FIG. 2, the adjusting member 230 is configured to move the pressing member 220 toward the reticle pressing board 210 along a first axial direction A1, so that the pushing portion 222 pushes the reticle pressing board 210 to move laterally relative to the pressing member 220 along a second axial direction A2. Specifically, the pressing member 220 further includes a body portion 221. The body portion 221 is for disposing the adjusting member 230. The pushing portion 222 is coupled to the body portion 221. The pushing portion 222 includes an elastic portion 222b and an inclined surface 222a coupled to the elastic portion 222b. The inclined surface 222a is on the elastic portion 222b and located on a side of the elastic portion 222b away from the body portion 221. The inclined surface 222a is inclined relative to the first axial direction A1 and the second axial direction A2. The pressing member 220 is adjusted according to the adjusting member 230, so that the reticle pressing board 210 is pushed toward the reticle 900 or away from the reticle 900 along an inclination angle of the inclined surface 222a, and the elastic portion 222b elastically deforms simultaneously with pushing force of the inclined surface 222a. It can be seen from this that the elastic portion 222b will elastically deform as the body portion 221 moves laterally. Through the pushing portion 222 that is elastically deformable, the pressing member 220 can simultaneously achieve the purpose of using the body portion 221 to abut against the reticle pressing board 210 and using the pushing portion 222 to laterally push the reticle pressing device 210.

In some embodiments, the inclined surface 222a is an inclined surface inclined relative to the first axial direction A1 and the second axial direction A2, but the disclosure is not limited thereto. In practical applications, the inclined surface 222a may be an arc surface.

In some embodiments, the first axial direction A1 and the second axial direction A2 are perpendicular to each other, but the disclosure is not limited thereto.

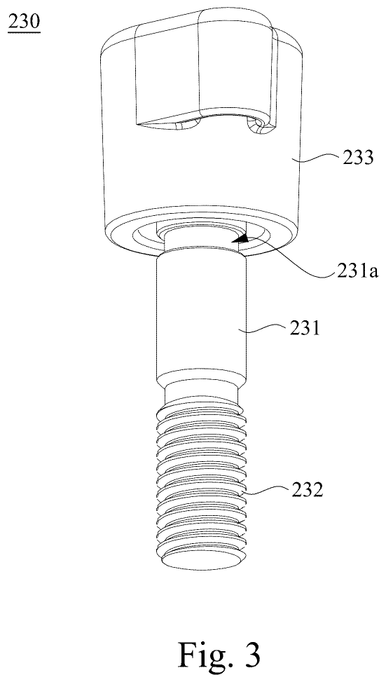

In some embodiments, the adjusting member 230 is rotatably coupled to the pressing member 220. For example, reference is made to FIG. 3. FIG. 3 is a perspective view of the adjusting member 230 in FIG. 1. As shown in FIG. 2 and FIG. 3, in the present embodiment, the pressing member 220 has a through hole 221a. The through hole 221a has an expansion hole portion 221a1 and a shrinkage hole portion 221a2 that are connected to each other. A hole diameter of the expansion hole portion 221a1 is greater than a hole diameter of the shrinkage hole portion 221a2. For example, an outline of the through hole 221a having the expansion hole portion 221a1 and the shrinkage hole portion 221a2 is similar to a gourd. The adjusting member 230 is placed in the expansion hole portion 221a1 and coupled and positioned toward the shrinkage hole portion 221a2.

Specifically, the adjusting member 230 includes a pillar 231 and a head portion 233. The head portion 233 is configured to abut against the pressing member 220 and away from a side of the reticle pressing board 210. An end of the pillar 231 is coupled to the head portion 233. The pillar 231 is disposed in the reticle pressing board 210 through the pressing member 220. The size of the through hole 221a is not suitable for the head portion 233 to pass through. For example, the expansion hole portion 221a1 is a part of the circular hole (but is not limited to this), and the hole diameter of the expansion hole portion 221a1 is equal to or greater than an outer diameter of the pillar 231, therefore the expansion hole portion 221a1 can be passed through by the pillar 231.

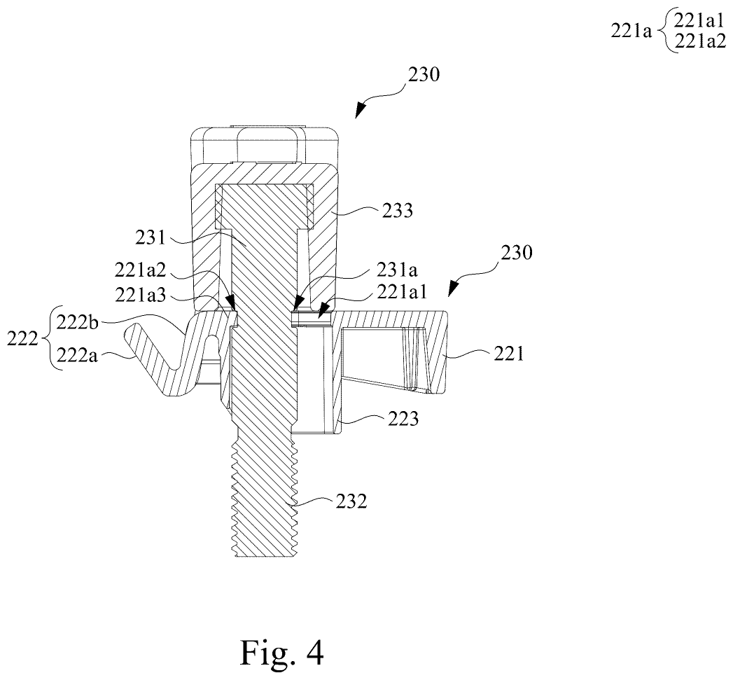

Reference is made to FIG. 4. FIG. 4 is a cross-sectional view of the pressing member 220 and the adjusting member 230 in FIG. 1. As shown in FIG. 3 and FIG. 4, in the present embodiment, the adjusting member 230 is configured to be rotatably coupled to the shrinkage hole portion 221a2 of the through hole 221a. Specifically, the shrinkage hole portion 221a2 has a flange 221a3 therein. In addition, the pillar 231 of the adjusting member 230 has an annular engaging groove 231a. The flange 221a3 is for coupling and positioning the annular engaging groove 231a. For example, the shrinkage hole portion 221a2 is a part of the circular hole, and the hole diameter of the shrinkage hole portion 221a2 is equal to or greater than an outer diameter of the annular engaging groove 231a and smaller than the outer diameter of the pillar 231, therefore the flange 221a3 is rotatably engaged with the annular engaging groove 231a.

In some embodiments, an outline of the shrinkage hole portion 221a2 is slightly greater than a semicircle, and the pillar 231 originally located in the expansion hole portion 221a1 can squeeze the annular engaging groove 231a into the shrinkage hole portion 221a2. Therefore, when the flange 221a3 is rotatably engaged with the annular engaging groove 231a, the adjusting member 230 can rotate relative to the pressing member 220. In this way, when the adjusting member 230 rotates, the pressing member 220 will not rotate together with the adjusting member 230.

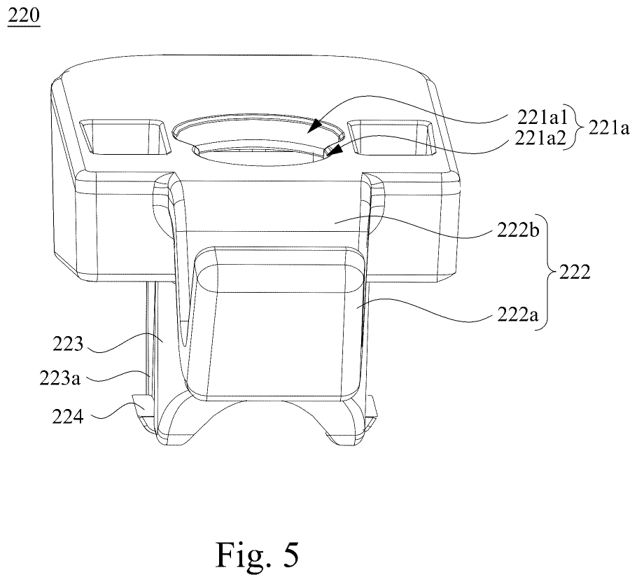

Reference is made to FIG. 5. FIG. 5 is a perspective view of the pressing member 220 in FIG. 1. As shown in FIG. 2 and FIG. 5, in the present embodiment, the reticle pressing board 210 has a mounting hole 211. The pressing member 220 passes through the mounting hole 211 and is configured to slide along the mounting hole 211. The inclined surface 222a on the pushing portion 222 pushes against an inner edge of the mounting hole 211, so that the reticle pressing board 210 moves laterally relative to the pressing member 220. Specifically, the mounting hole 211 extends, for example, along the second axial direction A2, and has two first retaining portions 211a opposite to each other and respectively on two sides of the mounting hole 211. The pressing member 220 includes a mounting portion 223. The body portion 221 of the pressing member 220 is configured to abut against one side of the reticle pressing board 210 (e.g., the top side of the reticle pressing board 210 in FIG. 2). The mounting portion 223 is connected to the body portion 221 and passes through the mounting hole 211. The mounting portion 223 has two second retaining portions 223a opposite to each other on two sides. The two second retaining portions 223a are configured to respectively abut against the two first retaining portions 211a. In this way, when the pressing member 220 passes through the mounting hole 211 and slides along the mounting hole 211, the two first retaining portions 211a of the mounting hole 211 will retain the two second retaining portions 223a of the mounting portion 223, so as to prevent the pressing member 220 from rotating relative to the reticle pressing board 210 around the first axial direction A1. It can be seen from this that when the adjusting member 230 rotates, the pressing member 220 of which the rotation is restricted by the reticle pressing board 210 will not rotate together with the adjusting member 230.

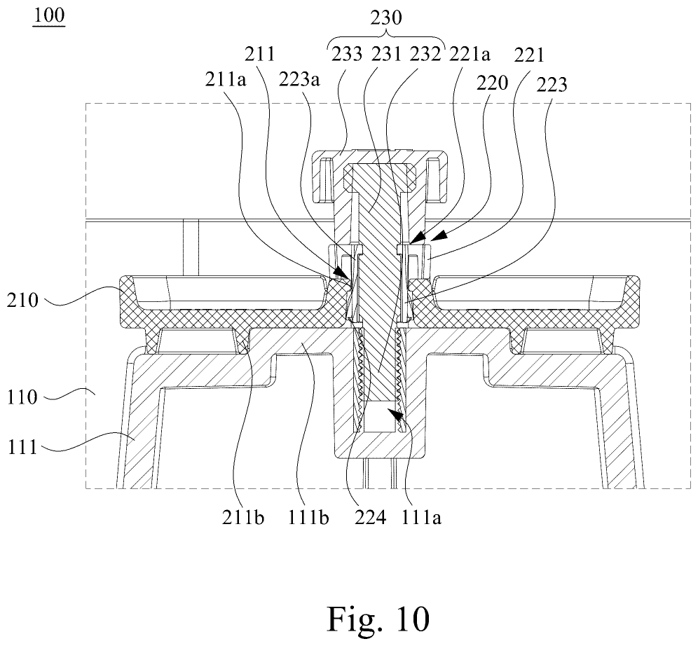

Furthermore, as shown in FIG. 2 and FIG. 5, in the present embodiment, the pressing member 220 further includes two engaging portions 224. The two engaging portions 224 are respectively connected to the two second retaining portions 223a of the mounting portion 223, and protrude in opposite directions relative to the mounting portion 223. The two engaging portions 224 are configured to engage with another side of the reticle pressing board 210 (e.g., the bottom side of the reticle pressing board 210 in FIG. 2, and please refer to FIG. 10 first), so that the reticle pressing board 210 is retained between the body portion 221 of the pressing member 220 and the two engaging portions 224. During actual assembly, the mounting portion 223 of the pressing member 220 can be inserted through the mounting hole 211 of the reticle pressing board 210. When the mounting portion 223 passes through the mounting hole 211, the two first retaining portions 211a of the mounting hole 211 and the two engaging portions 224 are pressed against each other. After being squeezed through the mounting hole 211, the two engaging portions 224 can be engaged with the another side of the reticle pressing board 210.

According to the foregoing structural configurations, through the coupling relationship between the adjusting member 230 and the shrinkage hole portion 221a2 of the pressing member 220 with the engaging relationship between the engaging portions 224 of the pressing member 220 and the reticle pressing board 210, the reticle pressing board 210 can move along with the adjusting member 230 together with the pressing member 220, thus increasing the operational convenience of the reticle pressing device 200.

As shown in FIG. 5, in the present embodiment, the engaging portions 224 are hook-shaped, but the present disclosure is not limited thereto.

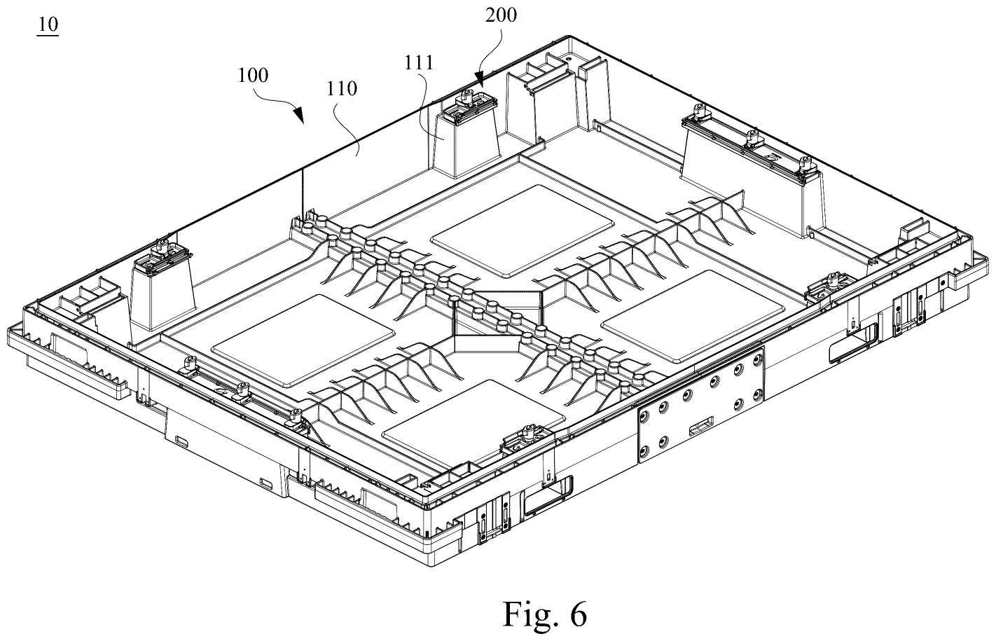

Reference is made to FIG. 6. FIG. 6 is a perspective view of a reticle box 10 according to an embodiment of the present disclosure. As shown in FIG. 6, in the present embodiment, the reticle box 10 includes a box body 100 and a plurality of reticle pressing device 200. The box body 100 includes a wall portion 110. The wall portion 110 surrounds to form an accommodating space. A plurality of platform portions 111 are disposed on an inner side of the wall portion 110 in an annular shape. The reticle pressing devices 200 are disposed on the platform portions 111.

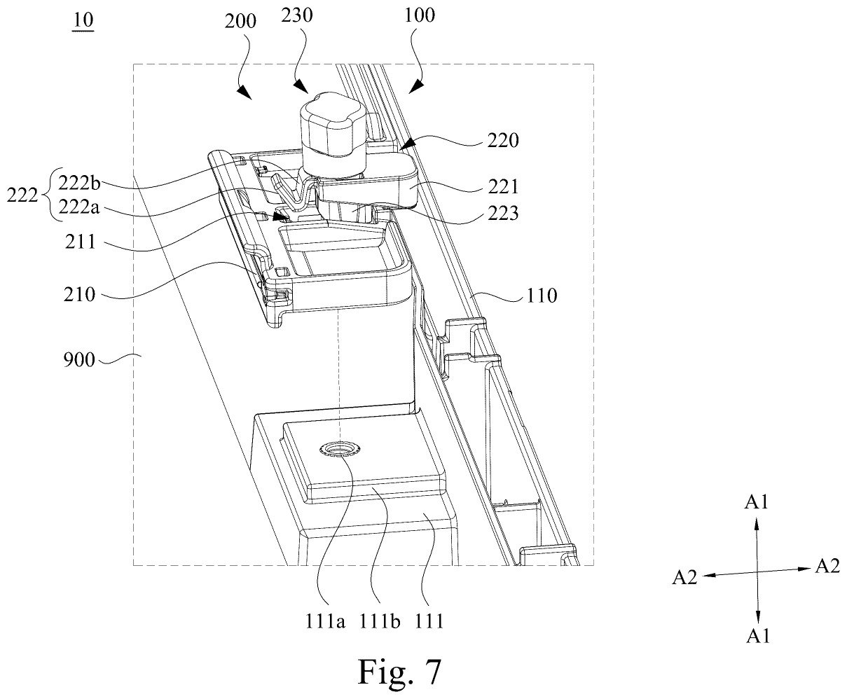

Reference is made to FIG. 7, FIG. 8, and FIG. 9. FIG. 7 is a partial enlarged exploded view of the box body 100 and the reticle pressing device 200 in FIG. 6. FIG. 8 is a partial enlarged perspective view of the box body 100 and the reticle pressing device 200 in FIG. 7. FIG. 9 is another partial enlarged perspective view of the box body 100 and the reticle pressing device 200 in FIG. 7. An assembler can install the reticle pressing devices 200 on the box body 100 according to the sequence of FIGS. 7 to 9, and use the reticle pressing devices 200 to hold the reticle 900 located in the accommodating space of the wall portion 110.

As shown in FIG. 7, in the present embodiment, each of the platform portions 111 has a fastening hole 111a. As mentioned above, through the coupling relationship between the adjusting member 230 and the shrinkage hole portion 221a2 of the pressing member 220 and the engaging relationship between the engaging portions 224 of the pressing member 220 and the reticle pressing board 210, the assembler can move the entire reticle pressing device 200 to above the platform portion 111 just by grasping the adjusting member 230.

As shown in FIG. 8 with reference to FIG. 3, in the present embodiment, the adjusting member 230 further includes a fastening portion 232. The fastening portion 232 is disposed at an end of the pillar 231 away from the head portion 233. The fastening portion 232 is located on the side of the reticle pressing board 210 away from the pressing member 220. The assembler holding the adjusting member 230 can move the entire reticle pressing device 200 toward the platform portion 111 to make the fastening portion 232 contact the fastening hole 111a, so that the reticle pressing device 200 and the platform portion 111 are initially aligned. According to the fastening degree of the fastening portion 232, the movement range of the pressing member 220 relative to the reticle pressing board 210 can be adjusted.

As shown in FIG. 9, in the present embodiment, the fastening portion 232 of the adjusting member 230 is configured to be fastened to the fastening hole 111a along the first axial direction A1. The assembler can fasten the fastening portion 232 downward to the fastening hole 111a by rotating the head portion 233 of the adjusting member 230. While the fastening portion 232 is completely fastened to the fastening hole 111a, the head portion 233 of the adjusting member 230 pushes the pressing member 220 toward the reticle pressing board 210 along the first axial direction A1, so as to make the inclined surface 222a of the pushing portion 222 push the reticle pressing board 210. In this way, the reticle pressing board 210 moves laterally along the second axial direction A2 relative to the pressing member 220 to leave the wall portion 110 and hold the reticle 900. When the fastening portion 232 is completely fastened to the fastening hole 111a, the body portion 221 of the pressing member 220 and the reticle pressing board 210 will be clamped between the platform portion 111 and the head portion 233 of the adjusting member 230.

When the assembler wants to disassemble the reticle pressing device 200 to release the reticle 900, the process from FIG. 9 to FIG. 7 can be performed, which will not be described again. As mentioned above, the reticle pressing board 210, the pressing member 220, and the adjusting member 230 are coupled together. When the fastening portion 232 is unlocked from the reticle box 10, the reticle pressing board 210, the pressing member 220, and the adjusting member 230 are removed from the reticle box 10 together.

Reference is made to FIG. 10. FIG. 10 is a partial cross-sectional view of the box body 100 and the reticle pressing device 200 in FIG. 7. As shown in FIG. 10, in the present embodiment, the platform portion 111 further has a guiding structure 111b. The guiding structure 111b is configured to guide the reticle pressing board 210 to move along the second axial direction A2. Specifically, the guiding structure 111b of the platform portion 111 is a bump. The bump extends along the second axial direction A2. In addition, the bottom of the reticle pressing board 210 also has a guiding structure 211b correspondingly. The guiding structure 211b of the reticle pressing board 210 includes two protruding ribs. The two protruding ribs extend along the second axial direction A2. The bump is slidably coupled between the two protruding ribs to guide the reticle pressing board 210 to move relative to the platform portion 111 along the second axial direction A2.

In some embodiments, the guiding structure 111b of the platform portion 111 and the guiding structure 211b of the reticle pressing board 210 can be interchanged with each other, and can also achieve the effect of mutual guidance.

According to the foregoing recitations of the embodiments of the disclosure, it can be seen that in the reticle pressing device of the present disclosure, when the adjusting member is adjusted (fastened) toward the reticle pressing board, the pressing member that moves toward the reticle pressing board together pushes the reticle pressing board to move laterally with the inclined surface thereof, thereby achieving the purpose of making the reticle pressing board clamp the reticle laterally. In the embodiment in which the adjusting member is coupled to the shrinkage hole portion of the pressing member, when the adjusting member rotates, the reticle pressing board will retain the location of the pressing member so that the pressing member does not rotate together with the adjusting member. In the embodiment in which the pressing member has an engaging portion for engaging with the reticle pressing board, cooperating with the coupling relationship between the adjusting member and the shrinkage hole portion of the pressing member, the reticle pressing board can move upward along with the adjusting member together with the pressing member after the adjusting member is completely loosened from the fastening hole of the reticle box, so that the whole reticle pressing device can be detached from the reticle box (that is, the operation convenience can be increased).

Although the present disclosure has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A reticle pressing device applied to a reticle box, the reticle box being used to accommodate a reticle, the reticle pressing device comprising:
a reticle pressing board;
a pressing member disposed on the reticle pressing board, the pressing member comprising a pushing portion, wherein the pushing portion pushes the reticle pressing board correspondingly according to a movement range of the pressing member toward the reticle pressing board, so as to make the reticle pressing board move laterally relative to the pressing member; and
an adjusting member disposed in the reticle pressing board through the pressing member, wherein the adjusting member is used to adjust the movement range of the pressing member, so that the pushing portion pushes toward the reticle pressing board until the reticle is fixed, or adjusts the pushing portion of the pressing member to move away from the reticle and release pushing force.

2. The reticle pressing device of claim 1, wherein the pushing portion comprises an elastic portion and an inclined surface coupled to the elastic portion, the pressing member is adjusted according to the adjusting member, so that the reticle pressing board is pushed toward the reticle or away from the reticle along an inclination angle of the inclined surface, and the elastic portion elastically deforms simultaneously with pushing force of the inclined surface.

3. The reticle pressing device of claim 1, wherein the pressing member moves toward the reticle pressing board along a first axial direction, so as to make the pushing portion push the reticle pressing board to move laterally relative to the pressing member along a second axial direction, and the pushing portion is inclined relative to the first axial direction and the second axial direction.

4. The reticle pressing device of claim 1, wherein the pressing member further comprises a body portion, the body portion is coupled to the pushing portion and for disposing the adjusting member, wherein the pushing portion comprises an elastic portion, and the elastic portion elastically deforms along with a lateral movement of the body portion.

5. The reticle pressing device of claim 1, wherein the adjusting member is rotatably coupled to the pressing member.

6. The reticle pressing device of claim 1, wherein the pressing member has a through hole, the through hole has an expansion hole portion and a shrinkage hole portion that are connected to each other, a hole diameter of the expansion hole portion is greater than a hole diameter of the shrinkage hole portion, and the adjusting member is placed in the expansion hole portion and coupled and positioned toward the shrinkage hole portion.

7. The reticle pressing device of claim 6, wherein the shrinkage hole portion has a flange therein for coupling and positioning an annular engaging groove of the adjusting member.

8. The reticle pressing device of claim 1, wherein the adjusting member comprises:
a head portion configured to abut against the pressing member and away from a side of the reticle pressing board;
a fastening portion configured to fasten the reticle box and adjust the movement range of the pressing member relative to the reticle pressing board according to a fastening degree of the fastening portion; and
a pillar, an end of the pillar being coupled to the head portion, another end of the pillar being coupled to the fastening portion, wherein the pillar is disposed in the reticle pressing board through the pressing member.

9. The reticle pressing device of claim 1, wherein the reticle pressing board, the pressing member, and the adjusting member are coupled together, the adjusting member comprises a fastening portion, the fastening portion is configured to fasten the reticle box, and when the fastening portion is unlocked from the reticle box, the reticle pressing board, the pressing member, and the adjusting member are removed from the reticle box together.

10. The reticle pressing device of claim 1, wherein:
the reticle pressing board has a mounting hole, and two first retaining portions are provided on two sides of the mounting hole respectively; and
the pressing member comprises a mounting portion, two second retaining portions are provided on two sides of the mounting portion, and the second retaining portions are respectively configured with the first retaining portions to retain each other.

11. A reticle box, comprising:
a box body comprising a wall portion, wherein a plurality of platform portions are disposed on an inner side of the wall portion in an annular shape, and each of the platform portions has a fastening hole; and
a reticle pressing device disposed in the box body, the box body having an accommodating space for accommodating a reticle, wherein the reticle pressing device comprises:
a reticle pressing board disposed on one of the platform portions;
a pressing member disposed on the reticle pressing board, the pressing member comprising a pushing portion, wherein the pushing portion pushes the reticle pressing board correspondingly according to a movement range of the pressing member toward the reticle pressing board, so as to make the reticle pressing board move laterally relative to the pressing member; and
an adjusting member disposed in the reticle pressing board through the pressing member, wherein the adjusting member has a fastening portion, the fastening portion is configured to fasten to the fastening hole and adjust the movement range of the pressing member relative to the reticle pressing board according to a fastening degree of the fastening portion.

12. The reticle box of claim 11, wherein the pushing portion comprises an elastic portion and an inclined surface coupled to the elastic portion, the pressing member is adjusted according to the adjusting member, so that the reticle pressing board is pushed toward the reticle or away from the reticle along an inclination angle of the inclined surface, and the elastic portion elastically deforms simultaneously with pushing force of the inclined surface.

13. The reticle box of claim 11, wherein the pressing member moves toward the reticle pressing board along a first axial direction, so as to make the pushing portion push the reticle pressing board to move laterally relative to the pressing member along a second axial direction, and the pushing portion is inclined relative to the first axial direction and the second axial direction.

14. The reticle box of claim 11, wherein the pressing member further comprises a body portion, the body portion is coupled to the pushing portion and for disposing the adjusting member, wherein the pushing portion comprises an elastic portion, and the elastic portion elastically deforms along with a lateral movement of the body portion.

15. The reticle box of claim 11, wherein the adjusting member is rotatably coupled to the pressing member.

16. The reticle box of claim 11, wherein the pressing member has a through hole, the through hole has an expansion hole portion and a shrinkage hole portion that are connected to each other, a hole diameter of the expansion hole portion is greater than a hole diameter of the shrinkage hole portion, and the adjusting member is placed in the expansion hole portion and coupled and positioned toward the shrinkage hole portion.

17. The reticle box of claim 16, wherein the shrinkage hole portion has a flange therein for coupling and positioning an annular engaging groove of the adjusting member.

18. The reticle box of claim 11, wherein the adjusting member further comprises:
a head portion configured to abut against the pressing member and away from a side of the reticle pressing board; and
a pillar, an end of the pillar being coupled to the head portion, another end of the pillar being coupled to the fastening portion, wherein the pillar is disposed in the reticle pressing board through the pressing member.

19. The reticle box of claim 11, wherein the reticle pressing board, the pressing member, and the adjusting member are coupled together, and when the fastening portion is unlocked from the reticle box, the reticle pressing board, the pressing member, and the adjusting member are removed from the reticle box together.

20. The reticle box of claim 11, wherein:
the reticle pressing board has a mounting hole, and two first retaining portions are provided on two sides of the mounting hole respectively; and
the pressing member comprises a mounting portion, two second retaining portions are provided on two sides of the mounting portion, and the second retaining portions are respectively configured with the first retaining portions to retain each other.
